(19) United States
(12) Patent Application Publication
(10) Pub. No.: US 2023/0352411 A1
(43) Pub. Date: Nov. 2, 2023

(54) SEMICONDUCTOR PACKAGE AND ELECTRONIC DEVICE INCLUDING THE SAME

(71) Applicant: Samsung Electronics Co., Ltd., Suwon-si (KR)

(72) Inventors: Yunseok Choi, Suwon-si (KR); Jongbo Shim, Suwon-si (KR); Heeyoub Kang, Suwon-si (KR); Sungeun Jo, Suwon-si (KR)

(21) Appl. No.: 18/090,856

(22) Filed: Dec. 29, 2022

(30) Foreign Application Priority Data
Apr. 27, 2022 (KR) 10-2022-0052231

(51) Int. Cl. H01L 23/538; H01L 25/16; H01L 23/12; H01L 23/498; H01L 23/66; H01L 23/00; H01L 23/31

(52) U.S. Cl. CPC H01L 23/538; H01L 25/16; H01L 23/12; H01L 23/49838; H01L 23/66; H01L 24/16; H01L 23/3157; H01L 2223/6672; H01L 2924/19011; H01L 2924/19041; H01L 2924/19042; H01L 2924/19043; H01L 2224/16237

(57) ABSTRACT

A semiconductor package includes a package substrate with first and second mounting regions at a top surface of the package substrate, a first semiconductor chip disposed on the first mounting region, a second semiconductor chip disposed on the second mounting region, an interposer substrate disposed on the second mounting region and covering the second semiconductor chip, a plurality of conductive connectors extending from a bottom surface of the interposer substrate to the top surface of the package substrate and laterally spaced apart from the second semiconductor chip, and a third semiconductor chip on a top surface of the interposer substrate. A first distance between a top surface of the first semiconductor chip and the top surface of the package substrate is greater than a second distance between the top surface of the interposer substrate and the top surface of the package substrate.

### CROSS-REFERENCE TO RELATED APPLICATION

This application is based on and claims priority under 35 U.S.C. § 119 to Korean Patent Application No. 10-2022-0052231, filed on Apr. 27, 2022, in the Korean Intellectual Property Office, the disclosure of which is incorporated by reference herein in its entirety.

### BACKGROUND

The inventive concept relates to a semiconductor package and an electronic device including the same, and more particularly, to a semiconductor package including a plurality of semiconductor chips and an electronic device including the semiconductor package.

Due to the rapid developments of the electronics industry and demands of users, electronic devices are becoming smaller and more lightweight, having more functions, and having higher capacity. Therefore, there is a demand for a semiconductor package including a plurality of semiconductor chips. For example, a method of mounting various types of semiconductor chips side by side on one package substrate or stacking semiconductor chips or packages on one package substrate may be used.

### SUMMARY

The inventive concept provides a semiconductor package including a plurality of semiconductor chips.

The inventive concept also provides an electronic device including the semiconductor package.

According to an aspect of the inventive concept, a semiconductor package includes a package substrate comprising a first mounting region and a second mounting region at a top surface of the package substrate, a first semiconductor chip disposed on the first mounting region of the package substrate, a second semiconductor chip disposed on the second mounting region of the package substrate, an interposer substrate disposed on the second mounting region of the package substrate and covering the second semiconductor chip, a plurality of conductive connectors extending from a bottom surface of the interposer substrate to the top surface of the package substrate and laterally spaced apart from the second semiconductor chip, and a third semiconductor chip on a top surface of the interposer substrate. A first distance between a top surface of the first semiconductor chip and the top surface of the package substrate is greater than a second distance between the top surface of the interposer substrate and the top surface of the package substrate.

According to an aspect of the inventive concept, a semiconductor package includes a package substrate comprising a first mounting region and a second mounting region, a first semiconductor chip disposed on the first mounting region of the package substrate, a plurality of first chip connection bumps arranged between the first semiconductor chip and the package substrate, a second semiconductor chip disposed on the second mounting region of the package substrate, a plurality of second chip connection bumps arranged between the second semiconductor chip and the package substrate, an interposer substrate disposed on the second mounting region of the package substrate and covering the second semiconductor chip, a first passive device disposed on the second mounting region of the package substrate, a second passive device attached to a bottom surface of the interposer substrate and spaced apart from the package substrate, a plurality of conductive connectors extending from the bottom surface of the interposer substrate to a top surface of the package substrate and laterally spaced apart from the second semiconductor chip, a third semiconductor chip on the interposer substrate, a third passive device attached to a bottom surface of the package substrate, and an external connection terminal attached to the bottom surface of the package substrate. A distance between a top surface of the interposer substrate and the top surface of the package substrate is 200 μm or less. A distance between a top surface of the first semiconductor chip and the top surface of the package substrate is selected from a range of 200 μm to 1,000 μm. A height of the third passive device measured downwardly from the bottom surface of the package substrate is less than a height of the external connection terminal measured downwardly from the bottom surface of the package substrate.

According to an aspect of the inventive concept, an electronic device includes a package substrate comprising a first mounting region and a second mounting region, a first semiconductor chip disposed on the first mounting region of the package substrate, a second semiconductor chip disposed on the second mounting region of the package substrate, an interposer substrate disposed on the second mounting region of the package substrate and covering the second semiconductor chip, a plurality of conductive connectors extending from a bottom surface of the interposer substrate to a top surface of the package substrate and laterally spaced apart from the second semiconductor chip, a third semiconductor chip on the interposer substrate, an external connection terminal attached to a bottom surface of the package substrate, a system board disposed below the package substrate and connected to the external connection terminal, and a heat sink covering a top surface of the first semiconductor chip. A first distance between the top surface of the first semiconductor chip and the top surface of the package substrate is greater than a second distance between a top surface of the interposer substrate and the top surface of the package substrate.

According to an aspect of the inventive concept, a method of manufacturing a semiconductor package includes preparing a package substrate comprising a first mounting region and a second mounting region, mounting a first semiconductor chip on the first mounting region of the package substrate, mounting a second semiconductor chip on the second mounting region of the package substrate, mounting an interposer substrate on the second mounting region of the package substrate to cover the second semiconductor chip, and disposing a third semiconductor chip on the interposer substrate. A first distance between a top surface of the first semiconductor chip and a top surface of the package substrate is greater than a second distance between a top surface of the interposer substrate and the top surface of the package substrate.

### BRIEF DESCRIPTION OF THE DRAWINGS

Embodiments of the inventive concept will be more clearly understood from the following detailed description taken in conjunction with the accompanying drawings in which:

FIG. 1 is a cross-sectional view of a semiconductor package according to embodiments;

FIG. 2 is a plan view of some components of the semiconductor package of FIG. 1;

FIG. 3 is a cross-sectional view of a semiconductor package according to embodiments;

FIG. 4 is a cross-sectional view of a semiconductor package according to embodiments;

FIG. 5 is a cross-sectional view of an electronic device according to embodiments; and

FIGS. 6A to 6E are cross-sectional views illustrating a method of manufacturing a semiconductor package, according to embodiments of the inventive concept.

### DETAILED DESCRIPTION OF THE EMBODIMENTS

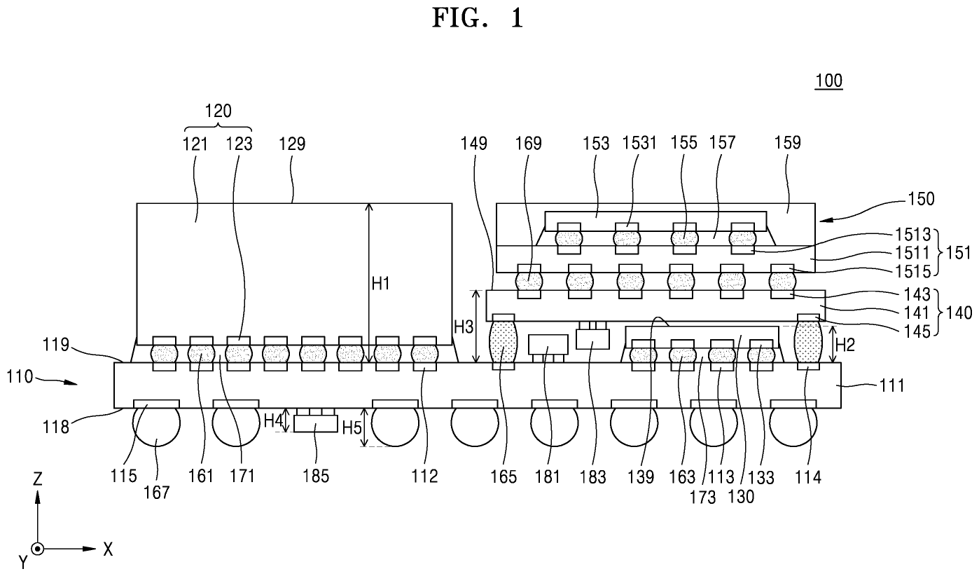

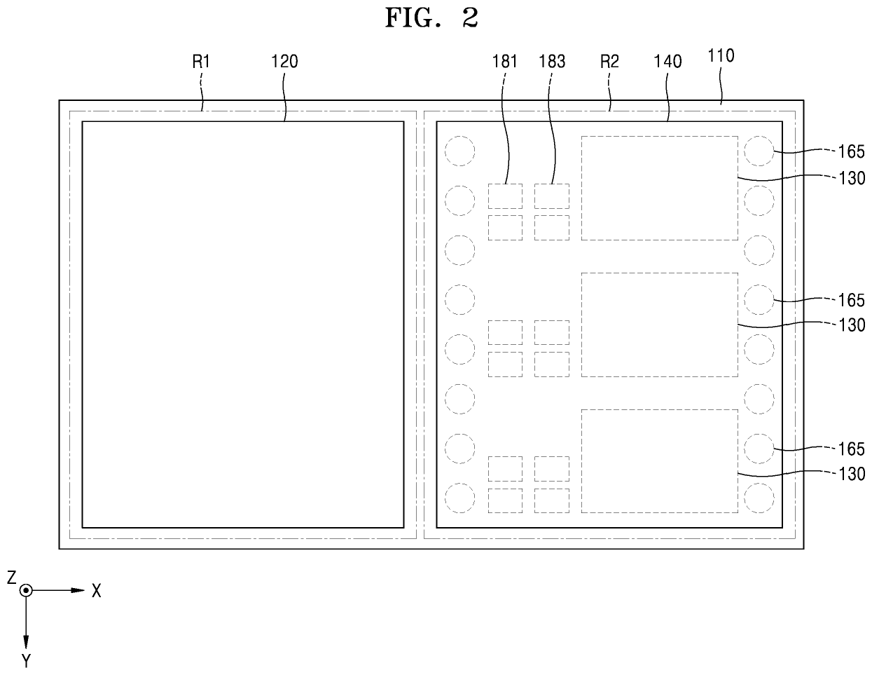

FIG. 1 is a cross-sectional view of a semiconductor package 100 according to embodiments. FIG. 2 is a plan view of some components of the semiconductor package 100 of FIG. 1.

Referring to FIGS. 1 and 2, the semiconductor package 100 may include a package substrate 110, a first semiconductor chip 120, a second semiconductor chip 130, an interposer substrate 140, a sub-package 150 including a third semiconductor chip 153, and first to third passive devices 181, 183, and 185.

The package substrate 110 may have a flat plate shape or a panel shape. The package substrate 110 may include a top surface 119 and a bottom surface 118 opposite to each other, and the top surface 119 and the bottom surface 118 may each be flat. Hereinafter, a horizontal direction (e.g., an X direction and/or a Y direction) may be defined as a direction parallel to the top surface 119 of the package substrate 110, and a vertical direction (e.g., a Z direction) may be defined as a direction perpendicular to the top surface 119 of the package substrate 110, and a horizontal width may be defined as a length in the horizontal direction (e.g., an X-direction and/or a Y-direction).

The package substrate 110 may include, at the top surface thereof, a first mounting region R1 and a second mounting region R2 spaced apart from each other. The first semiconductor chip 120 may be disposed on the first mounting region R1 of the package substrate 110. The second semiconductor chip 130, the interposer substrate 140, and the sub-package 150 may be arranged on the second mounting region R2 of the package substrate 110.

The package substrate 110 may be, for example, a printed circuit board (PCB). The package substrate 110 may include a core insulation layer 111, first upper connection pads 112, second upper connection pads 113, third upper connection pads 114, and lower connection pads 115.

The core insulation layer 111 may include or may be formed of at least one material selected from among phenol resin, epoxy resin, and polyimide. For example, the core insulation layer 111 may include or may be formed of at least one material selected from among polyimide, Flame Retardant 4 (FR-4), tetrafunctional epoxy, polyphenylene ether, epoxy/polyphenylene oxide, Bismaleimide triazine (BT), Thermount, cyanate ester, and a liquid crystal polymer.

The first upper connection pads 112, the second upper connection pads 113, and the third upper connection pads 114 may be provided at the top surface of the core insulation layer 111. The first upper connection pads 112 may be provided at the first mounting region R1 of the package substrate 110, and the second upper connection pads 113 and the third upper connection pads 114 may be provided at the second mounting region R2 of the package substrate 110. The lower connection pads 115 may be provided at the bottom surface of the core insulation layer 111. Internal interconnect patterns electrically and physically connected to the first upper connection pads 112, the second upper connection pads 113, the third upper connection pads 114, and the lower connection pads 115 may be provided inside the core insulation layer 111.

For example, the first upper connection pads 112, the second upper connection pads 113, the third upper connection pads 114, and the lower connection pads 115 may each include or may be formed of metal, such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), and an alloy thereof.

External connection terminals 167 may be respectively attached to the lower connection pads 115 of the package substrate 110. An external device may be electrically and physically connected to the package substrate 110 using the external connection terminals. The external connection terminals 167 may include or may be, for example, solder balls or solder bumps.

One or more first semiconductor chips 120 may be mounted on the first mounting region R1 of the package substrate 110. A first semiconductor chip 120 may include a first semiconductor substrate 121 and first chip pads 123. The top surface and bottom surface of first semiconductor substrate 121 may be opposite to each other. The bottom surface of the first semiconductor substrate 121 may be an active surface of the first semiconductor substrate 121, and the top surface of the first semiconductor substrate 121 may be an inactive surface of the first semiconductor substrate 121. The first semiconductor substrate 121 may include or may be a semiconductor wafer or a portion thereof. The first semiconductor substrate 121 may include or may be formed of, for example, silicon (Si). In embodiments, the first semiconductor substrate 121 may include a semiconductor element, such as germanium (Ge). In embodiments, the first semiconductor substrate 121 may include or may be formed of a compound semiconductor, such as silicon carbide (SiC), gallium arsenide (GaAs), indium arsenide (InAs), and indium phosphide (InP). The first semiconductor substrate 121 may include a conductive region, e.g., a well doped with an impurity or a structure doped with an impurity. A semiconductor device layer including individual devices may be provided at the active surface of the first semiconductor substrate 121. The individual devices may include, for example, transistors. The individual devices may include microelectronic devices, e.g., a metal-oxide-semiconductor field effect transistor (MOSFET), a system large scale integration (LSI), an image sensor, such as a CMOS imaging sensor (CIS), a micro-electro-mechanical system (MEMS), an active device, a passive device, etc. The first chip pads 123 are provided at the bottom surface of the first semiconductor chip 120 and may be electrically connected to the individual devices of the semiconductor device layer.

The first semiconductor chip 120 may be mounted on the package substrate 110 by a flip-chip manner in which the first semiconductor chip 120 may be directly connected to first chip connection bumps 161 deposited on the second upper connection pads 113 of the package substrate 110. The first semiconductor chip 120 may be electrically and physically connected to the package substrate 110 through first chip connection bumps 161. The first chip connection bumps 161 may be respectively attached to the first chip pads 123 of the first semiconductor chip 120 and the first upper connection pads 112 of the package substrate 110. The first chip connection bumps 161 may include or may be solder bumps. A first underfill layer 171 may be provided between the first semiconductor chip 120 and the top surface 119 of the package substrate 110. The first underfill layer 171 may be formed to fill a gap between the package substrate 110 and the first semiconductor chip 120 and surround a sidewall of each of the first chip connection bumps 161. The first underfill layer 171 may include or may be formed of an underfill material, such as epoxy resin and a non-conductive film. According to embodiments, a top surface 129 and sidewalls of the first semiconductor chip 120 may be exposed to the outside of the semiconductor package 100. According to embodiments, a heat sink may be attached to the top surface 129 of the first semiconductor chip 120.

One or more second semiconductor chips 130 may be mounted on the second mounting region R2 of the package substrate 110. A second semiconductor chip 130 may be electrically connected to the first semiconductor chip 120 through an electrical connection path provided at the package substrate 110. The second semiconductor chip 130 may include a second semiconductor substrate and second chip pads 133. A material constituting the second semiconductor substrate may be substantially the same as or similar to the material constituting the first semiconductor substrate 121 of the first semiconductor chip 120. A semiconductor device layer including individual devices may be provided at the bottom surface of the second semiconductor substrate. The second chip pads 133 may be provided at the bottom surface of the second semiconductor chip 130 and may be electrically connected to the individual devices of the semiconductor device layer of the second semiconductor chip 130. Terms such as “same,” “equal,” “planar,” or “coplanar,” as used herein encompass near identicality including variations that may occur, for example, due to manufacturing processes. The term “substantially” may be used herein to emphasize this meaning, unless the context or other statements indicate otherwise.

The second semiconductor chip 130 may be mounted on the package substrate 110 by flip-chip manner. The second semiconductor chip 130 may be electrically and physically connected to the package substrate 110 through second chip connection bumps 163. The second chip connection bumps 163 may be attached to the second chip pads 133 of the second semiconductor chip 130 and the second upper connection pads 113 of the package substrate 110. The second chip connection bumps 163 may include or may be solder bumps. A second underfill layer 173 may be provided between the second semiconductor chip 130 and the top surface 119 of the package substrate 110. The second underfill layer 173 may be formed to fill a gap between the package substrate 110 and the second semiconductor chip 130 and surround a sidewall of each of the second chip connection bumps 163. The second underfill layer 173 may include or may be formed of an underfill material, such as epoxy resin and a non-conductive film. In embodiments, the second semiconductor chip 130 may have no direct connection to the interposer substrate 140.

The interposer substrate 140 may be mounted on the second mounting region R2 of the package substrate 110. The interposer substrate 140 is disposed above the second semiconductor chip 130 and may cover the second semiconductor chip 130. The interposer substrate 140 may have a plate shape and may include a top surface 149 and a bottom surface opposite to each other. The interposer substrate 140 may include a base insulation layer 141, upper pads 143, and lower pads 145.

The base insulation layer 141 may include or may be formed of at least one material selected from among phenol resin, epoxy resin, and polyimide. For example, the base insulation layer 141 may include or may be formed of at least one material selected from among polyimide, FR-4, tetrafunctional epoxy, polyphenylene ether, epoxy/polyphenylene oxide, Bismaleimide triazine (BT), Thermount, cyanate ester, and a liquid crystal polymer. According to some embodiments, the interposer substrate 140 may include or may be formed of Si, e.g., crystalline Si, polycrystalline Si, or amorphous Si. The base insulation layer 141 may have a plate shape with flat top and bottom surfaces opposite to each other.

The upper pads 143 may be provided at the top surface 149 of the interposer substrate 140, and the lower pads 145 may be provided at the bottom surface of the interposer substrate 140. The upper pads 143 and the lower pads 145 may be electrically connected with each other through an interconnect structure provided in the base insulation layer 141. The upper pads 143 and the lower pads 145 may include or may be formed of a material substantially the same as or similar to the material constituting the first upper connection pads 112 of the package substrate 110 as described above. The lower pads 145 may respectively contact first conductive connectors 165 provided below the interposer substrate 140, and the upper pads 143 may respectively contact second conductive connectors 169 provided on the interposer substrate 140. The term “contact,” as used herein, refers to a direct connection (i.e., touching) unless the context indicates otherwise.

The interposer substrate 140 may be electrically connected to the package substrate 110 through the first conductive connectors 165. The first conductive connectors 165 may be arranged between the interposer substrate 140 and the package substrate 110 and may be laterally spaced apart from the second semiconductor chip 130. Each of the first conductive connectors 165 may extend from a corresponding one of third upper connection pads 114 of the package substrate 110 to a corresponding one of lower pads 145 of the interposer substrate 140 in the vertical direction (e.g., the Z direction). The first conductive connectors 165 may each have a column-like shape. For example, the horizontal width of each of the first conductive connectors 165 may be largest at the middle portion thereof between the lower end thereof and the upper end thereof. The lower end of each of the first conductive connectors 165 and the upper end thereof may contact the package substrate 110 and the interposer substrate 140, respectively. For example, the horizontal width of each of the first conductive connectors 165 may gradually increase from the lower end thereof to the middle portion and then, gradually decrease from the middle portion thereof to the upper end thereof. The first conductive connectors 165 may include or may be formed of, for example, a conductive material, such as solder, gold, silver, and copper.

The sub-package 150 may be mounted on the interposer substrate 140 through the second conductive connectors 169. According to embodiments, the sub-package 150 may include a mounting substrate 151, one or more third semiconductor chips 153, and a sub-molding layer 159.

The mounting substrate 151 may be, for example, a PCB. The mounting substrate 151 may include a base insulation layer 1511, upper pads 1513 provided at the top surface of the base insulation layer 1511, and lower pads 1515 provided at the bottom surface of the base insulation layer 1511. The base insulation layer 1511 may include or may be formed of at least one material selected from among phenol resin, epoxy resin, and polyimide. The upper pads 1513 and the lower pads 1515 may include or may be formed of a conductive material, such as Cu and Al. The upper pads 1513 and the lower pads 1515 may be electrically connected with each other through an interconnect structure provided in the base insulation layer 1511. The one or more third semiconductor chips 153 may be mounted on the mounting substrate 151 through connection bumps 155. For example, two or more third semiconductor chips 153 spaced apart in a lateral direction may be mounted on the mounting substrate 151. The connection bumps 155 may be connected to third chip pads 1531 of the third semiconductor chip 153 and the upper pads 1513 of the mounting substrate 151, respectively. An underfill layer 157 may be provided between the third semiconductor chip 153 and the mounting substrate 151. The underfill layer 157 may fill a gap between the third semiconductor chip 153 and the mounting substrate 151 and surround a sidewall of each of the connection bumps 155. The sub-molding layer 159 may be disposed on the top surface of the mounting substrate 151 and cover the third semiconductor chip 153. The sub-molding layer 159 may include or may be formed of epoxy-based molding resin or polyimide-based molding resin. For example, the sub-molding layer 159 may include or may be formed of an epoxy molding compound.

According to some embodiments, the sub-package 150 may be omitted and the third semiconductor chip 153 may be directly mounted on the interposer substrate 140. In this case, the third semiconductor chip 153 may be directly mounted on the interposer substrate 140 through the second conductive connectors 169 provided between the third chip pads 1531 and the upper pads 143 of the interposer substrate 140, and the top surface and sidewalls of the third semiconductor chip 153 may be exposed to the outside of the semiconductor package 100.

First to third semiconductor chips 120, 130, and 153 may include different types of semiconductor chips and may be electrically connected to one another through the package substrate 110 and/or the interposer substrate 140. The first to third semiconductor chips 120, 130, and 153 may each include a memory chip, a logic chip, a system on chip (SOC), a power management integrated circuit (PMIC) chip, a radio frequency integrated circuit (RFIC) chip, etc. The memory chip may include a dynamic random access memory (DRAM) chip, a static random access memory (SRAM) chip, a magnetoresistive random access memory (MRAM) chip, a NAND flash memory chip, and/or a high bandwidth memory (HBM) chip. The logic chip may include an application processor (AP), a microprocessor, a central processing unit (CPU), a controller, and/or an application specific integrated circuit (ASIC). For example, the SOC may include at least two circuits from among a logic circuit, a memory circuit, a digital integrated circuit (IC), an RFIC, and an input/output circuit.

According to embodiments, the dimension of the first semiconductor chip 120 may be larger than the dimension of the second semiconductor chip 130 and the dimension of the third semiconductor chip 153. For example, the thickness of the first semiconductor chip 120 may be greater than the thickness of the second semiconductor chip 130 and the thickness of the third semiconductor chip 153, and the horizontal width of the first semiconductor chip 120 may be greater than the horizontal width of the second semiconductor chip 130 and the horizontal width of the third semiconductor chip 153. According to embodiments, the top surface 129 of the first semiconductor chip 120 may be substantially coplanar with the top surface of the sub-package 150 or the top surface of the third semiconductor chip 153. As the first semiconductor chip 120 is formed to have a relatively large dimension, the heat spreading characteristic of the first semiconductor chip 120 may be improved.

A distance H1 between the top surface 129 of the first semiconductor chip 120 and the package substrate 110 (e.g., a top surface of the package substrate 110) may be greater than a distance H2 between the top surface 139 of the second semiconductor chip 130 and the package substrate 110. The distance H1 between the top surface 129 of the first semiconductor chip 120 and the package substrate 110 may be selected from a range of 200 μm to 1,000 μm. According to embodiments, the distance H2 between the top surface 139 of the second semiconductor chip 130 and the package substrate 110 may be 100 μm or less. For example, the distance H2 between the top surface 139 of the second semiconductor chip 130 and the package substrate 110 may be between about 50 μm and about 100 μm. Terms such as “about” or “approximately” may reflect amounts, sizes, orientations, or layouts that vary only in a small relative manner, and/or in a way that does not significantly alter the operation, functionality, or structure of certain elements. For example, a range from “about 0.1 to about 1” may encompass a range such as a 0%-5% deviation around 0.1 and a 0% to 5% deviation around 1, especially if such deviation maintains the same effect as the listed range.

The distance H1 between the top surface 129 of the first semiconductor chip 120 and the package substrate 110 may be greater than a distance H3 between the top surface 149 of the interposer substrate 140 and the package substrate 110. When the distance H1 between the top surface 129 of the first semiconductor chip 120 and the package substrate 110 is selected from a range of 200 μm to 1,000 μm, the distance H3 between the top surface 149 of the interposer substrate 140 and the package substrate 110 may be 200 μm or less. For example, the distance H3 between the top surface 149 of the interposer substrate 140 and the package substrate 110 may be between about 150 μm and about 200 μm. According to some embodiments, a difference between the distance H1 between the top surface 129 of the first semiconductor chip 120 and the package substrate 110 and the distance H3 between the top surface 149 of the interposer substrate 140 and the package substrate 110 may be 200 μm or more, e.g., between about 200 μm and about 800 μm.

According to embodiments, the first semiconductor chip 120 may be a type of a semiconductor chip that generates relatively more heat than the second semiconductor chip 130 and the third semiconductor chip 153. For example, the first semiconductor chip 120 may include a logic chip and/or an SOC, the second semiconductor chip 130 may include a PMIC chip and/or an RFIC chip, and the third semiconductor chip 153 may include a memory chip. According to embodiments, the first semiconductor chip 120 may be a type of a semiconductor chip (e.g., a logic chip and/or an SOC) that generates a first amount of heat, the second semiconductor chip 130 may be a type of a semiconductor chip (e.g., a PMIC chip and/or an RFIC chip) that generates a second amount of heat less than the first amount of heat, and the third semiconductor chip 153 may be a type of a semiconductor chip (e.g., a memory chip) that generates a third amount of heat less than the first amount of heat. In embodiments, the second amount of heat may be smaller than the third amount of heat. In embodiments, an amount of heat generated by a semiconductor chip may be an amount of heat, per a unit area and per a time unit, generated in operation.

The semiconductor package 100 may further include passive devices attached to the package substrate 110 and/or the interposer substrate 140. The passive devices may be surface-mount devices (SMDs). The passive devices may include capacitors, resistors, inductors, etc.

According to embodiments, the semiconductor package 100 may include a first passive device 181 attached to the top surface 119 of the package substrate 110, a second passive device 183 attached to the bottom surface of the interposer substrate 140, and a third passive device 185 attached to the bottom surface 118 of the package substrate 110. The first passive device 181 may be mounted on the second mounting region R2 of the package substrate 110 and may be laterally spaced apart from the second semiconductor chip 130. The second passive device 183 may be attached to the bottom surface of the interposer substrate 140 and may be laterally spaced apart from the first passive device 181 and the second semiconductor chip 130. The third passive device 185 may be attached to the bottom surface 118 of the package substrate 110 and may be laterally spaced apart from the external connection terminals 167.

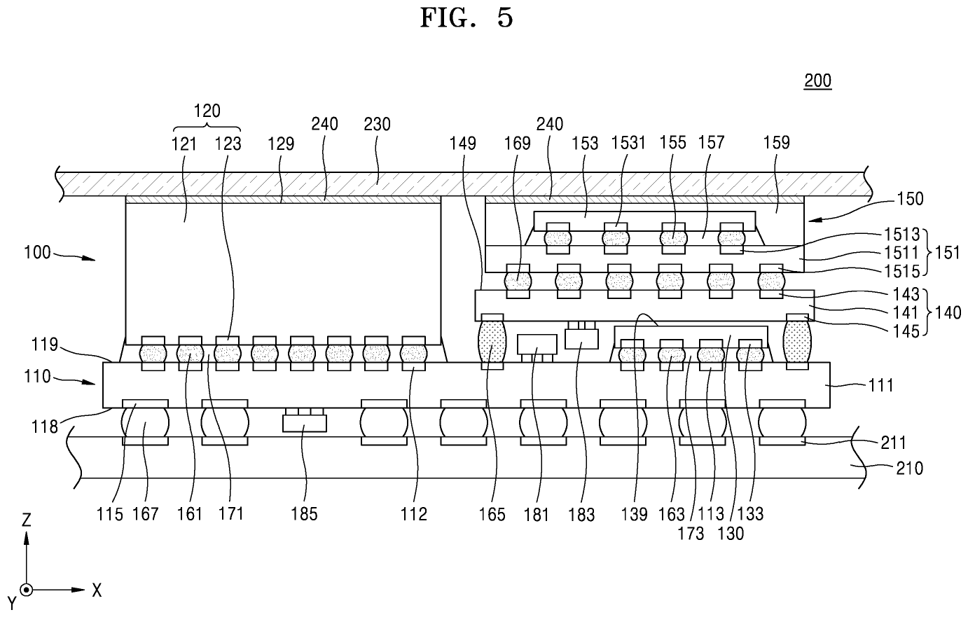

According to embodiments, the height of the third passive device 185, measured downwardly from the bottom surface 118 of the package substrate 110, may be less than the height of the external connection terminals 167, measured from the bottom surface 118 of the package substrate 110. For example, a distance H4 between the lowermost end of the third passive device 185 and the bottom surface 118 of the package substrate 110 may be less than a distance H5 between the lowermost end of the external connection terminals 167 and the bottom surface 118 of the package substrate 110. For example, when the distance H4 between the lowermost end of the third passive device 185 and the bottom surface 118 of the package substrate 110 is selected from a range of about 100 μm to about 150 μm, the distance H5 between the lowermost end of the external connection terminal 167 and the package substrate 110 may be selected from a range of 150 μm to 250 μm. Since the height of the third passive device 185 is less than the height of the external connection terminals 167, when the semiconductor package 100 is mounted on a mounting substrate of an external device (e.g., a system board 210 of FIG. 5), the third passive device 185 may be spaced apart from the mounting substrate of the external device, thereby preventing physical interference between the third passive device 185 and the mounting substrate of the external device.

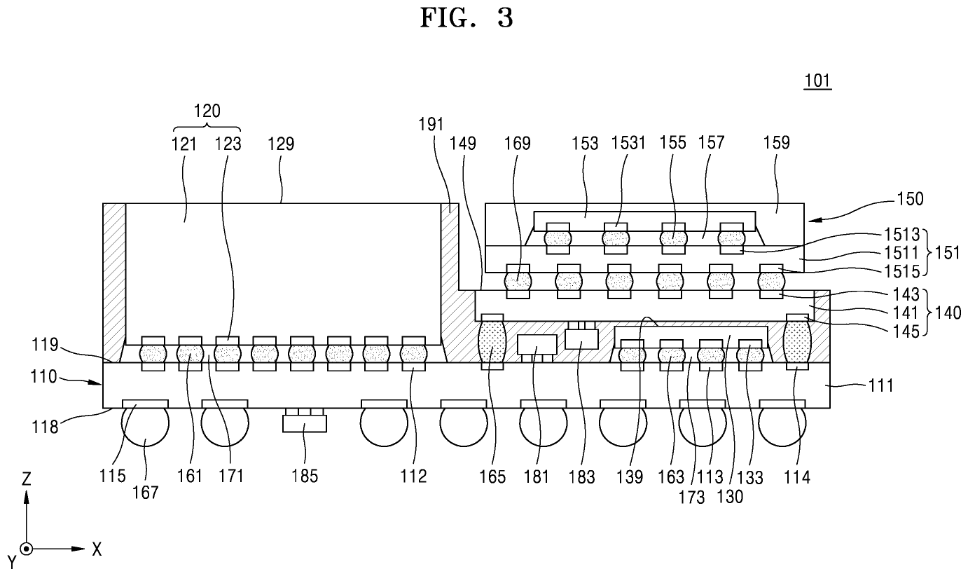

FIG. 3 is a cross-sectional view of a semiconductor package 101 according to embodiments. Hereinafter, the semiconductor package 101 of FIG. 3 will be described based on differences from the semiconductor package 100 as described above with reference to FIGS. 1 and 2.

Referring to FIG. 3, the semiconductor package 101 may further include a molding layer 191 disposed on the top surface 119 of the package substrate 110 compared to the semiconductor package 100 of FIGS. 1 and 2.

The molding layer 191 may extend along sidewalls of the first semiconductor chip 120 and surround the sidewalls of the first semiconductor chip 120. The molding layer 191 may not cover the top surface 129 of the first semiconductor chip 120. The top surface 129 of the first semiconductor chip 120 may be exposed to the outside of the molding layer 191 through a first surface of the molding layer 191 that is at the same plane as the top surface 129 of the first semiconductor chip 120. For example, the first surface of the molding layer 191 may be coplanar with the top surface 129 of the first semiconductor chip 120.

The molding layer 191 may extend along sidewalls of the interposer substrate 140 and surround the sidewalls of the interposer substrate 140. The molding layer 191 may not cover the top surface 149 of the interposer substrate 140. The top surface 149 of the interposer substrate 140 may be exposed to the outside of the molding layer 191 through a second surface of the molding layer 191 that is at the same plane as the top surface 149 of the interposer substrate 140. For example, the second surface of the molding layer 191 may be coplanar with the top surface 149 of the interposer substrate 140. In some embodiments, the molding layer 191 may have a stepped top surface with the first and second surfaces, and the second surface of the molding layer 191 may be lower than the first surface of the molding layer 191.

Furthermore, the molding layer 191 may be formed to fill a gap between the interposer substrate 140 and the package substrate 110. The molding layer 191 may contact the bottom surface of the interposer substrate 140, the second semiconductor chip 130, the first passive device 181, the second passive device 183, and the first conductive connectors 165. The molding layer 191 may cover the top surface 139 and sidewalls of the second semiconductor chip 130 and may surround sidewalls of the first conductive connectors 165.

For example, the molding layer 191 may include or may be formed of epoxy-based molding resin or polyimide-based molding resin. For example, the molding layer 191 may include or may be formed of an epoxy molding compound.

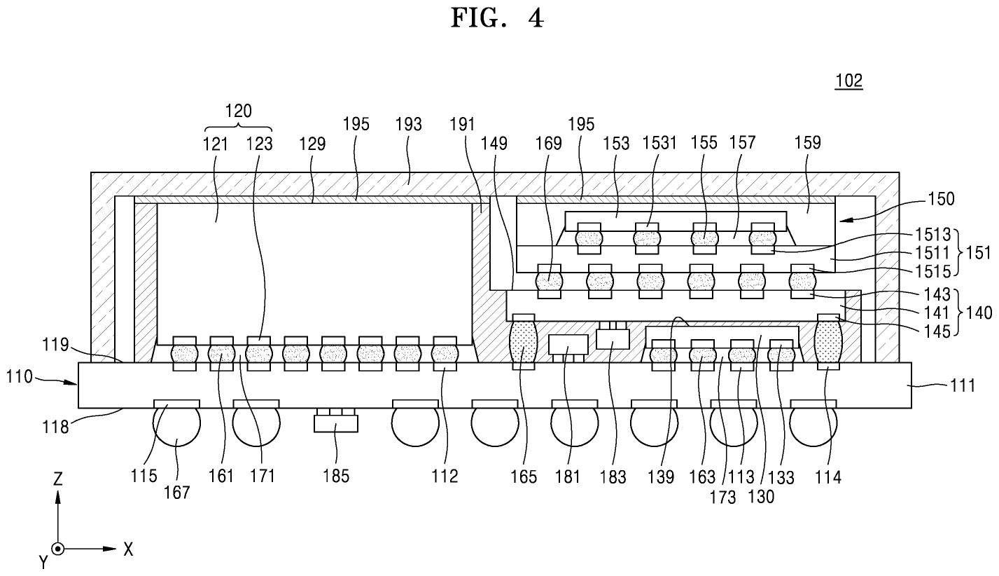

FIG. 4 is a cross-sectional view of a semiconductor package 102 according to embodiments of the inventive concept. Hereinafter, the semiconductor package 102 of FIG. 4 will be described based on differences from the semiconductor package 101 as described above with reference to FIG. 3.

Referring to FIG. 4, the semiconductor package 102 may further include a heat sink 193 attached to the first semiconductor chip 120 and/or the sub-package 150 as compared to the semiconductor package 101 of FIG. 3. For example, the heat sink 193 may be attached on the top surface 119 of the package substrate 110. The heat sink 193 may include sidewalls attached to the package substrate 110 at regions adjacent to edges of the top surface 119 of the package substrate 110 and a cover plate covering the first semiconductor chip 120 and the sub-package 150.

The heat sink 193 may be configured to dissipate heat generated by the first semiconductor chip 120 and/or the sub-package 150. The heat sink 193 may include or may be formed of a thermally conductive material having high thermal conductivity. For example, the heat sink 193 may include or may be formed of metal, such as Cu and Al, or a carbon-containing material, such as graphene, graphite, and carbon nanotubes. However, materials constituting the heat sink 193 are not limited to the above-described materials. According to embodiments, the heat sink 193 may include or may be a single metal layer or a plurality of stacked metal layers.

Thermal interface material (TIM) layers 195 may be disposed between the heat sink 193 and the first semiconductor chip 120 and between the heat sink 193 and the sub-package 150. The heat sink 193 may be attached to the top surface 129 of the first semiconductor chip 120 and the top surface of the sub-package 150 through the TIM layers 195. The TIM layers 195 may include or may be formed of a thermally conductive and electrically insulating material. For example, the TIM layers 195 may include or may be formed of a polymer including a metal powder, such as silver and Cu, thermal grease, white grease, or a combination thereof.

FIG. 5 is a cross-sectional view of an electronic device 200 according to embodiments.

Referring to FIG. 5, the electronic device 200 may include the semiconductor package 100, the system board 210, and a heat sink 230.

The system board 210 may be referred to as a main board, a motherboard, etc. The package substrate 110 may be mounted on the system board 210. Conductive pads 211 of the system board 210 may be respectively coupled to external connection terminals 167. The system board 210 may include a PCB including an interface for connecting main components, such as a CPU or RAM for operating a system, to peripheral devices.

The semiconductor package 100 may be mounted on the system board 210. The first to third semiconductor chips 120, 130, and 153 of the semiconductor package 100 may be electrically connected to other electronic components mounted on the system board 210 through the external connection terminals 167 and the system board 210. Although FIG. 5 shows that the semiconductor package 100 is the semiconductor package 100 shown in FIGS. 1 and 2, the semiconductor package 101 shown in FIG. 3 may be mounted on the system board 210.

The heat sink 230 may be attached onto the first semiconductor chip 120 and/or the sub-package 150. Furthermore, the heat sink 230 may be attached to other electronic components mounted on the system board 210. The material constituting the heat sink 230 may be substantially the same as or similar to the material constituting the heat sink 193 as described with reference to FIG. 4 above. TIM layers 240 may be disposed between the heat sink 230 and the first semiconductor chip 120 and between the heat sink 230 and the sub-package 150. The heat sink 230 may be attached to the top surface 129 of the first semiconductor chip 120 and the top surface of the sub-package 150 through the TIM layers 240. The material constituting the TIM layers 240 may be substantially the same as or similar to the material constituting the TIM layers 195 as described above with reference to FIG. 4.

According to embodiments, a semiconductor chip having a relatively large thickness to be advantageous for heat dissipation may be disposed on the first mounting region (R1 of FIG. 2) of the package substrate 110, and semiconductor chips having relatively small thicknesses may be stacked on the second mounting region (R2 of FIG. 2) of the package substrate 110 by using the interposer substrate 140, thereby providing the semiconductor package 100 including a plurality of semiconductor chips and having a distinguished form factor. According to embodiments, in consideration of heat dissipation characteristics of semiconductor chips to be mounted on the package substrate 110, a first semiconductor chip required to have a first thickness (e.g., a relatively large thickness) is disposed on the first mounting region (R1 of FIG. 2) of the package substrate 110, and second semiconductor chips having thicknesses (e.g., a relatively small thickness) smaller than the first thickness are disposed on the second mounting region (R2 of FIG. 2). The second semiconductor chips may be stacked using the interposer substrate 140. The second semiconductor chips may be of the same type of a semiconductor device or different types of semiconductors. In embodiments, the semiconductor package 100 may include various types of semiconductors having different thicknesses and heat dissipation characteristics without increasing the package thickness and/or the package area.

Furthermore, according to embodiments, since a plurality of semiconductor chips are electrically connected to one another through the package substrate 110 and the interposer substrate 140 at the package level, the complexity of the routing structure of the system board 210 of the electronic device 200 may be reduced.

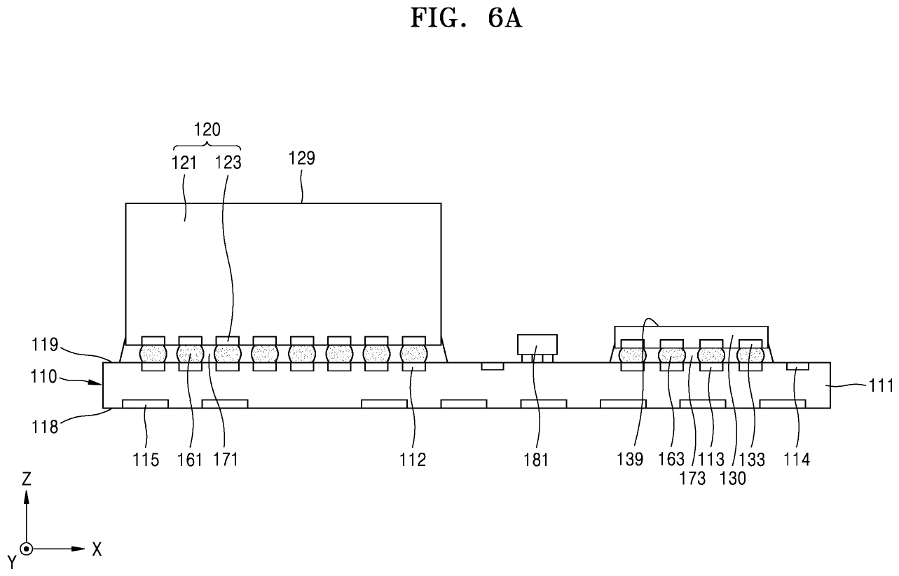

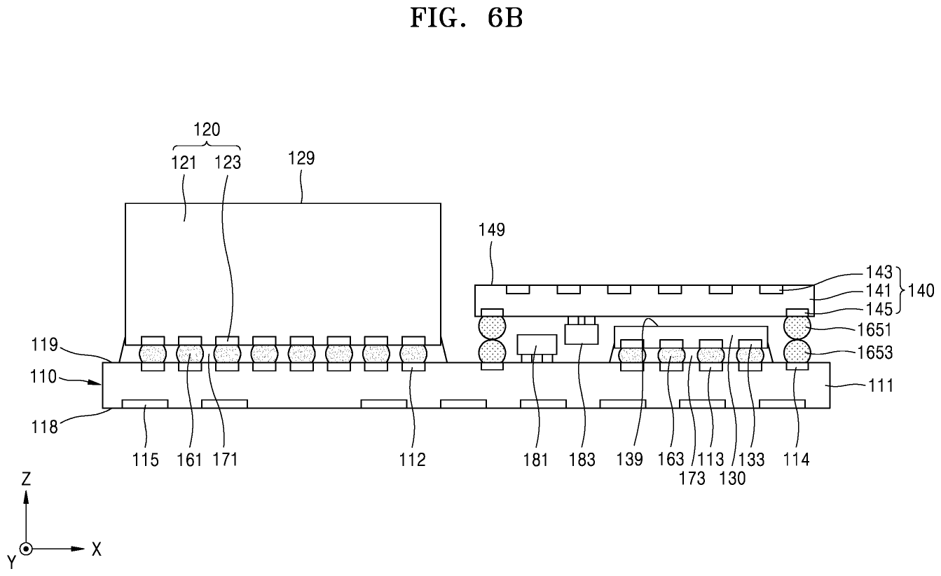

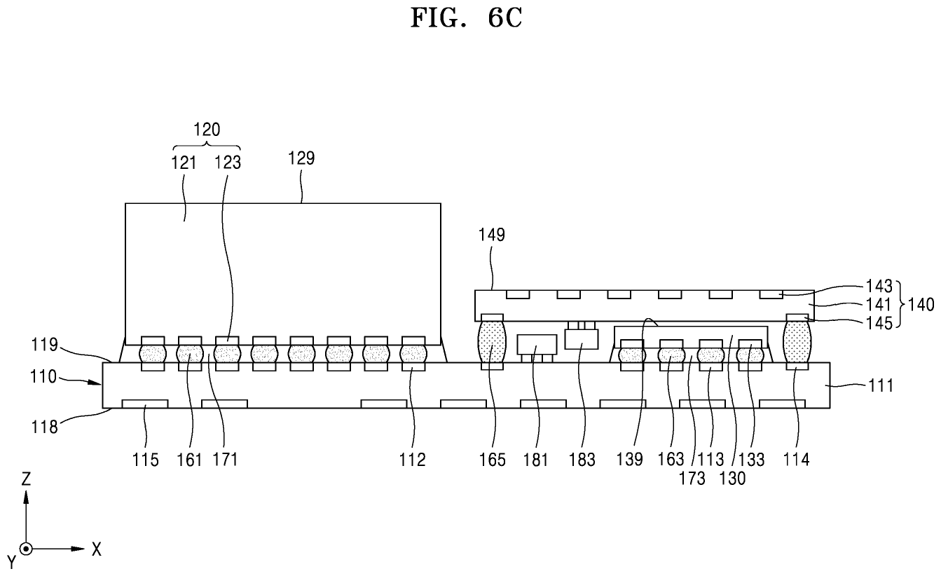

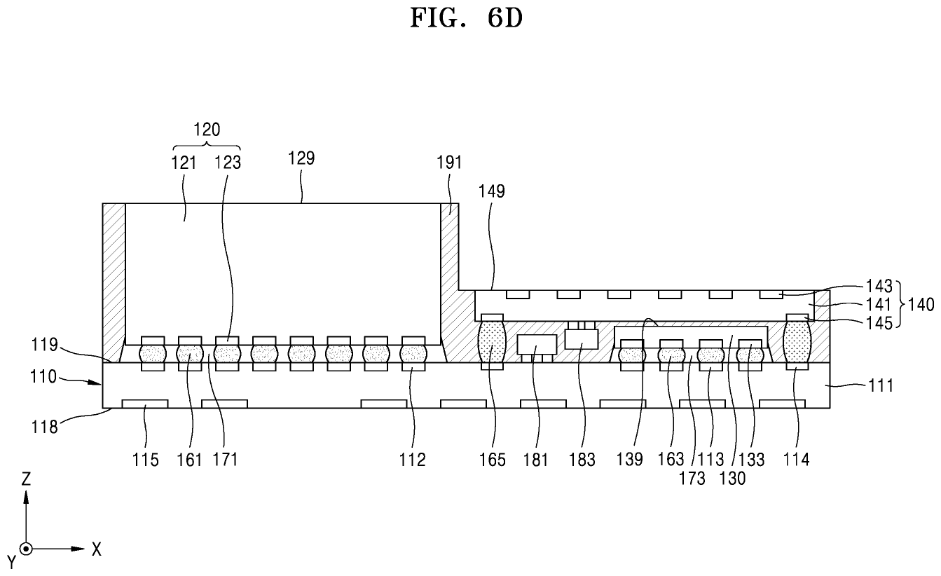

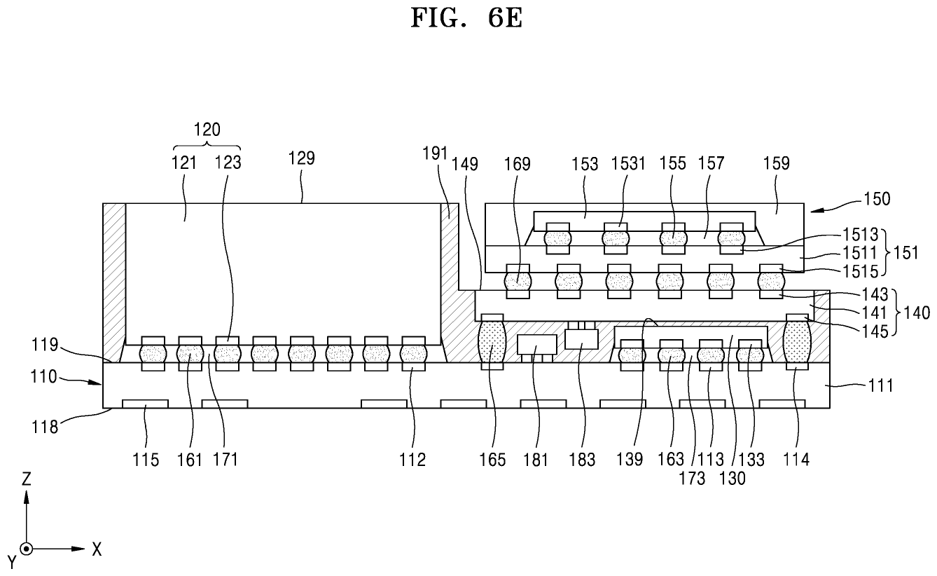

FIGS. 6A to 6E are cross-sectional views illustrating a method of manufacturing a semiconductor package, according to embodiments of the inventive concept.

Referring to FIG. 6A, the package substrate 110 including the first mounting region R1 and the second mounting region R2 is prepared. Thereafter, the first semiconductor chip 120, the second semiconductor chip 130, and the first passive device 181 are mounted on the package substrate 110. A process of mounting the first semiconductor chip 120 may include placing the first semiconductor chip 120 on the first mounting region R1 of the package substrate 110 and performing a thermo-compression bonding process or a reflow operation on the first chip connection bumps 161. A process of mounting the second semiconductor chip 130 may include placing the second semiconductor chip 130 on the second mounting region R2 of the package substrate 110 and performing a thermo-compression bonding process or a reflow operation on the second chip connection bumps 163. A mounting process of the first passive device 181 may include placing the first passive device 181 on the second mounting region R2 of the package substrate 110 and performing a thermo-compression bonding process or a reflow operation on conductive bumps of the first passive device 181. The process of mounting the first semiconductor chip 120, the process of mounting the second semiconductor chip 130, and the process of mounting the first passive device 181 may be performed simultaneously or at different times.

After the first semiconductor chip 120 and the second semiconductor chip 130 are mounted on the package substrate 110, the first underfill layer 171 filling a gap between the first semiconductor chip 120 and the package substrate 110 and the second underfill layer 173 filling a gap between the second semiconductor chip 130 and the package substrate 110 are formed. For example, the first underfill layer 171 and the second underfill layer 173 may be formed through a capillary underfill process.

Referring to FIGS. 6B and 6C, the interposer substrate 140 is prepared. The interposer substrate 140 may include first sub-connectors 1651 respectively attached onto the lower pads 145. The second passive device 183 may be attached to the bottom surface of the interposer substrate 140. The second passive device 183 may be attached to the bottom surface of the interposer substrate 140 through a thermo-compression bonding process or a reflow process with respect to conductive bumps of the second passive device 183.

After the interposer substrate 140 is placed such that the first sub-connectors 1651 attached to the interposer substrate 140 and second sub-connectors 1653 attached onto the third upper connection pads 114 of the package substrate 110 contact each other, a thermo-compression bonding process or a reflow process may be performed on the first sub-connectors 1651 and the second sub-connectors 1653. The first sub-connectors 1651 and the second sub-connectors 1653 may be coupled to each other through the thermo-compression bonding process or the reflow process, and thus, the first conductive connectors 165 may be formed. In embodiments, in the thermo-compression bonding process or the reflow process, the first sub-connectors 1651 and the second sub-connectors 1653 may reflow to form the first conductive connectors 165.

Referring to FIG. 6D, after the interposer substrate 140 is mounted on the package substrate 110, the molding layer 191 may be formed. The molding layer 191 may be formed to surround sidewalls of the first semiconductor chip 120 and sidewalls of the interposer substrate 140. The molding layer 191 is formed to fill a gap between the interposer substrate 140 and the package substrate 110 and may contact the first conductive connectors 165, the first passive device 181, the second passive device 183, and the second semiconductor chip 130. The molding layer 191 may be formed to not cover the top surface 129 of the first semiconductor chip 120 and the top surface 149 of the interposer substrate 140. For example, in a molding process, the top surface 129 of the first semiconductor chip 120 and the top surface 149 of the interposer substrate 140 may be covered with a block layer which may prevent the molding layer 191 from covering the top surface 129 of the first semiconductor chip 120 and the top surface 149 of the interposer substrate 140. Since the top surface 129 of the first semiconductor chip 120 has a higher vertical level than the top surface 149 of the interposer substrate 140, the molding layer 191 may be formed to have a stepped portion in the vicinity of the boundary between the first semiconductor chip 120 and the interposer substrate 140.

Referring to FIG. 6E, the sub-package 150 is mounted on the interposer substrate 140. The sub-package 150 may be mounted on the interposer substrate 140 through the second conductive connectors 169. According to some embodiments, the sub-package 150 may be replaced with a single third semiconductor chip 153, and the third semiconductor chip 153 may be directly mounted on the interposer substrate 140 through the second conductive connectors 169. After the sub-package 150 is mounted on the interposer substrate 140, as shown in FIG. 3, the third passive device 185 may be mounted on the bottom surface 118 of the package substrate 110 and the external connection terminals 167 may be formed on the bottom surface 118 of the package substrate 110.

While the inventive concept has been particularly shown and described with reference to embodiments thereof, it will be understood that various changes in form and details may be made therein without departing from the spirit and scope of the following claims.

What is claimed is:

1. A semiconductor package comprising:
a package substrate comprising a first mounting region and a second mounting region at a top surface of the package substrate;
a first semiconductor chip disposed on the first mounting region of the package substrate;
a second semiconductor chip disposed on the second mounting region of the package substrate;
an interposer substrate disposed on the second mounting region of the package substrate and covering the second semiconductor chip;
a plurality of conductive connectors extending from a bottom surface of the interposer substrate to the top surface of the package substrate and laterally spaced apart from the second semiconductor chip; and
a third semiconductor chip on a top surface of the interposer substrate,
wherein a first distance between a top surface of the first semiconductor chip and the top surface of the package substrate is greater than a second distance between the top surface of the interposer substrate and the top surface of the package substrate.

2. The semiconductor package of claim 1,
wherein the top surface of the first semiconductor chip is exposed to the outside of the semiconductor package.

3. The semiconductor package of claim 1,
wherein the second distance between the top surface of the interposer substrate and the top surface of the package substrate is 200 μm or less, and
wherein the first distance between the top surface of the first semiconductor chip and the top surface of the package substrate is selected from a range of 200 μm to 1,000 μm.

4. The semiconductor package of claim 3,
wherein a third distance between a top surface of the second semiconductor chip and the top surface of the package substrate is 100 μm or less.

5. The semiconductor package of claim 1, further comprising:
a first passive device disposed on the second mounting region of the package substrate; and
a second passive device attached to the bottom surface of the interposer substrate.

6. The semiconductor package of claim 1, further comprising:
a third passive device attached to a bottom surface of the package substrate; and
an external connection terminal attached to the bottom surface of the package substrate,
wherein a distance between a lowermost end of the third passive device and the bottom surface of the package substrate is less than a distance between a lowermost end of the external connection terminal and the bottom surface of the package substrate.

7. The semiconductor package of claim 1,
wherein the first semiconductor chip comprises a logic chip,
wherein the second semiconductor chip comprises at least one of a power management integrated circuit chip and a radio frequency integrated circuit chip, and
wherein the third semiconductor chip comprises a memory chip.

8. The semiconductor package of claim 1, further comprising:
a heat sink covering the top surface of the first semiconductor chip.

9. The semiconductor package of claim 1, further comprising:
a molding layer including a first portion surrounding sidewalls of the first semiconductor chip without covering the top surface of the first semiconductor chip,
wherein a top surface of the molding layer is coplanar with the top surface of the first semiconductor chip.

10. The semiconductor package of claim 9,
wherein the molding layer further comprises a second portion that is disposed between the bottom surface of the interposer substrate and each of the top surface of the package substrate and a top surface of the second semiconductor chip, and
wherein the second portion contacts the second semiconductor chip and each conductive conductor of the plurality of conductive connectors.

11. The semiconductor package of claim 10,
wherein the molding layer does not cover the top surface of the interposer substrate.

12. A semiconductor package comprising:
a package substrate comprising a first mounting region and a second mounting region;
a first semiconductor chip disposed on the first mounting region of the package substrate;
a plurality of first chip connection bumps arranged between the first semiconductor chip and the package substrate;
a second semiconductor chip disposed on the second mounting region of the package substrate;
a plurality of second chip connection bumps arranged between the second semiconductor chip and the package substrate;
an interposer substrate disposed on the second mounting region of the package substrate and covering the second semiconductor chip;
a first passive device disposed on the second mounting region of the package substrate;
a second passive device attached to a bottom surface of the interposer substrate and spaced apart from the package substrate;
a plurality of conductive connectors extending from the bottom surface of the interposer substrate to a top surface of the package substrate and laterally spaced apart from the second semiconductor chip;
a third semiconductor chip on the interposer substrate;
a third passive device attached to a bottom surface of the package substrate; and
an external connection terminal attached to the bottom surface of the package substrate,
wherein a distance between a top surface of the interposer substrate and the top surface of the package substrate is 200 μm or less,
wherein a distance between a top surface of the first semiconductor chip and the top surface of the package substrate is selected from a range of 200 μm to 1,000 μm, and
wherein a height of the third passive device measured downwardly from the bottom surface of the package substrate is less than a height of the external connection terminal measured downwardly from the bottom surface of the package substrate.

13. The semiconductor package of claim 12,
wherein the first semiconductor chip comprises a logic chip,
wherein the second semiconductor chip comprises at least one of a power management integrated circuit chip and a radio frequency integrated circuit chip,
wherein the third semiconductor chip comprises a memory chip, and
wherein the semiconductor package further comprises a heat sink contacting the top surface of the first semiconductor chip.

14. The semiconductor package of claim 12, further comprising:
a first underfill layer disposed between the first semiconductor chip and the package substrate and surrounding a sidewall of each first chip connection bump of the plurality of first chip connection bumps; and
a second underfill layer disposed between the second semiconductor chip and the package substrate and surrounding a sidewall of each second chip connection bump of the plurality of second chip connection bumps.

15. The semiconductor package of claim 12, further comprising:
a molding layer contacting the first semiconductor chip, the second semiconductor chip, the interposer substrate, and each conductive connector of the plurality of conductive connectors, wherein
wherein the molding layer does not cover the top surface of the first semiconductor chip and the top surface of the interposer substrate.

16. An electronic device comprising:
a package substrate comprising a first mounting region and a second mounting region;
a first semiconductor chip disposed on the first mounting region of the package substrate;
a second semiconductor chip disposed on the second mounting region of the package substrate;
an interposer substrate disposed on the second mounting region of the package substrate and covering the second semiconductor chip;
a plurality of conductive connectors extending from a bottom surface of the interposer substrate to a top surface of the package substrate and laterally spaced apart from the second semiconductor chip;
a third semiconductor chip on the interposer substrate;
an external connection terminal attached to a bottom surface of the package substrate;
a system board disposed below the package substrate and connected to the external connection terminal; and
a heat sink covering a top surface of the first semiconductor chip,
wherein a first distance between the top surface of the first semiconductor chip and the top surface of the package substrate is greater than a second distance between a top surface of the interposer substrate and the top surface of the package substrate.

17. The electronic device of claim 16, further comprising:
a first passive device disposed on the second mounting region of the package substrate;
a second passive device attached to the bottom surface of the interposer substrate; and
a third passive device attached to the bottom surface of the package substrate and spaced apart from the system board.

18. The electronic device of claim 16,
wherein the second distance between the top surface of the interposer substrate and the top surface of the package substrate is 200 μm or less,
wherein the first distance between the top surface of the first semiconductor chip and the top surface of the package substrate is 1,000 μm or less,
wherein a difference between the first distance between the top surface of the first semiconductor chip and the top surface of the package substrate and the second distance between the top surface of the interposer substrate and the top surface of the package substrate is equal to or greater than 200 μm, and
wherein a third distance between a top surface of the second semiconductor chip and the top surface of the package substrate is 100 μm or less.

19. The electronic device of claim 16,
wherein the first semiconductor chip comprises a logic chip,
wherein the second semiconductor chip comprises at least one of a power management integrated circuit chip and a radio frequency integrated circuit chip, and
wherein the third semiconductor chip comprises a memory chip.

20. The electronic device of claim 16, further comprising:
a molding layer contacting the first semiconductor chip, the second semiconductor chip, the interposer substrate, and each conductive connector of the plurality of conductive connectors,
wherein the molding layer does not cover the top surface of the interposer substrate.

21-25. (canceled)
